(19) United States
(12) Patent Application Publication
(10) Pub. No.: US 2002/0124203 A1
(43) Pub. Date: Sep. 5, 2002

(54) Method for utilizing DRAM memory

(76) Inventor: Henry Fang, Lo-Tung town (TW)

Correspondence Address: J.C. Patents, Inc., 4 Venture, Suite 250, Irvine, CA, 92618, US

(21) Appl. No.: 09/788,834

(22) Filed: Feb. 20, 2001

(51) Int. Cl. H03K 19/003

(52) U.S. Cl. 714/8

(57) ABSTRACT

A method of utilizing DRAM which may contain defective memory locations. The invention describes a method and two algorithms. In a data processing system a processor will make requests to a memory using logical addresses. A translator is used to determine what physical address in the memory device corresponds to a logical address. In the general methodology, a set of logical addresses is assigned corresponding to physical memory locations. The memory device is then mapped to determine which memory locations are defective. The invention outlines a method where a defective physical address that corresponds to a logical address is swapped with a non-defective physical address. The advantages of the invention include not needing redundant memory, fuses, a time consuming burn-in procedure, and allowing the device to repair memory locations that might become defective during the operation of the device.

### BACKGROUND OF INVENTION

1. Field of the Invention

The present invention relates to a semiconductor memory devices such as DRAM, and in particular to maximizing data storage capability through address remapping.

2. Description of the Related Art

Electronic devices are becoming increasingly more dependent on the ability to store, and retrieve data. This has led to a high demand for reliable memory devices that can be produced at a minimum cost. As electronic devices become smaller in size there is also a need for integrated circuits such as memory devices to be as compact as possible, while not sacrificing any operational characteristics.

One of the most popular memory devices is the Dynamic Random Access Memory (DRAM). DRAM is composed of a number of memory cells that are arranged in rows, and columns allowing devices to access memory locations through the use of memory addresses. As designers try to minimize device size, the size of individual memory cells also decreases. However due to material impurities and processing variations this has led to an increase in defective memory cells within a memory device. A modern DRAM can contain tens of thousands of memory cells, but the failure of a relatively small number of cells can lead to the discarding of a device, adding to the cost for a manufacturer.

To address these concerns there are many methods used by manufacturers to minimize product waste, and product failure. A common method is to use redundant cells that are selectively used to repair memory sections in case of failure. Usually this is accomplished through the use of selectively activated “fuses” that are manufactured into the memory device. If a memory section is found to be defective at the time of manufacture a fuse will be blown most often through the use of a laser in order to route logic to redundant memory cells. This method causes many problems. The device must be created with redundant memory cells which can take up valuable space. The creation of fuses in the device adds to its complexity, and cost. The device must be tested to identify defective memory which usually consists of memory testing, bit mapping, and after laser trimming the memory must be tested again, all of which are time consuming processes. Once a fuse is blown it cannot be unblown and the alteration is permanent for the lifetime of the device. Most importantly a process of laser trimming leaves particle residue on the die surface which can cause device shorts, and leakage.

Most device manufacturers also perform a burn-in procedure as part of the memory device testing. The burn-in procedure can accelerate the infant mortality of a weak cell that might otherwise become defective during the operation of the device. Burn-in procedures are time consuming especially for high pin count devices, and therefore increases the manufacturing cost.

It should be noted that all of the above procedures occur at the time of manufacture and cannot be of use if a memory cell fails during the devices lifetime. Memory cell operational failure can cause large problems including loss of data, inefficient performance, or even device failure. This may result in the memory device having to be replaced. A particular case where this can be very costly is with an embedded DRAM (eDRAM). In an eDRAM the DRAM is enclosed in a much larger unit. If a failure occurs in the eDRAM portion of the unit it can necessitate the entire unit being discarded which can be very cost prohibitive.

Therefore a need exists for a memory repair method that does not require damaging fuses, or time-consuming burn-in procedures. There also exists a need for a memory repair system that can repair memory cells that might fail during the operational lifetime of the memory system.

### SUMMARY OF THE INVENTION

A method used to solve some of the prior arts problems is to use redundant memory. Repairs of defective areas in memory devices is accomplished by replacing them with addresses of a redundant section of memory. This method is problematic however because adding redundant memory will increase the size of the device. In addition the use of redundant memory adds to the complexity of the semiconductor memory architecture, and can draw added power consumption.

The present invention addresses these problems by providing a method for utilizing a memory device as to maximize its memory potential, by minimizing or eliminating the use of bad memory locations. The method does not require redundant memory and therefore eliminates the problems therein. In the envisioned device a processor accesses memory through a memory bus. A memory bus retrieves or stores data to a DRAM by utilizing a second memory device which acts as a translator. The translator translates logical addresses from the processor, and processor bus, into the physical addresses of the DRAM where the data is to be retrieved or stored. The present invention provides a method and two algorithms for efficiently converting the physical memory addresses into logical addresses as to maximize the potential of the memory for the processor, and decrease waste and manufacturing costs. While the invention may be utilized in a wide variety of memory devices it is particularly useful for Embedded DRAM (eDRAM) memory.

The invention does not require the use of fuses and therefore has less manufacturing complexity, and time consuming testing procedures. The invention also does not require a burn-in after manufacture which saves on time, and cost. The invention further does not need redundant memory for address remapping.

The method of the invention can be used at time of manufacture. Parameters can be set up by a manufacturer wherein if a certain operating efficiency is achieved through the repair method described herein the device is acceptable, and if not the chip can be flagged as an incomplete memory. The address remapping method described herein can also be used during the lifetime of the device. This allows for the repair of memory locations that might fail during the devices operation. This will allow the device to operate more efficiently over its lifetime, or perhaps even extend its lifetime.

These and other features, which characterize the invention, are set forth in the claims annexed hereto and forming a further part hereof. However, for a better understanding of the invention, and of the advantages and objectives attained through its use, reference should be made to the Drawings, and to the accompanying descriptive matter, in which there is described exemplary embodiments of the invention.

### BRIEF DESCRIPTION OF THE DRAWINGS

FIG. 1 is a block diagram of a data processing system consistent with the invention.

FIG. 2 is a hardware block diagram of the DRAM repairing method that is consistent with the invention.

FIG. 3 is a flowchart illustrating an embodiment of the invention for a memory repairing method.

FIG. 4 is a diagram that exemplifies the Rainbow Swapping algorithm

FIG. 5 is a flowchart illustrating an embodiment of the invention for a memory repairing method.

FIG. 6 is a diagram that exemplifies the Stack Swapping algorithm.

### DETAILED DESCRIPTION

In the following detailed description of the preferred embodiments, reference is made to the accompanying drawings which form a part hereof, and in which is shown by way of illustration specific preferred embodiments in which the invention may be practiced. The preferred embodiments are described in sufficient detail to enable these skilled in the art to practice the invention, and it is to be understood that other embodiments may be utilized and that logical changes may be made without departing from the spirit and scope of the present invention. The following detailed description is, therefore, not to be taken in a limiting sense, and the scope of the present invention is defined only be the appended claims.

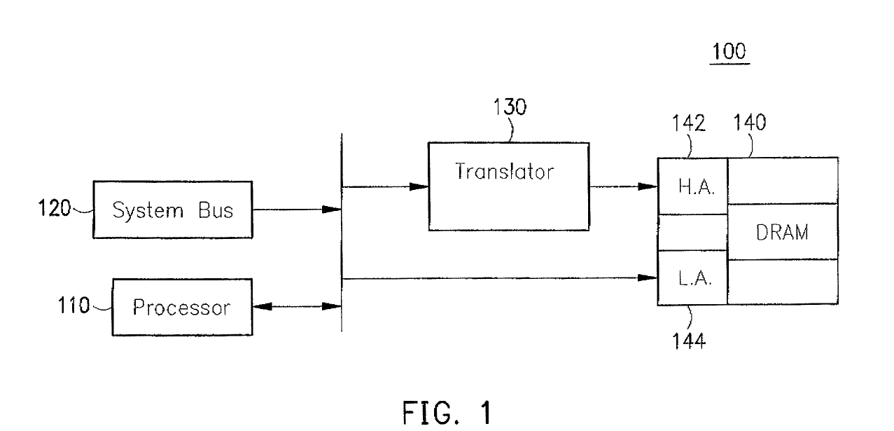

Turning to the drawings, FIG. 1 shows a block diagram of a data processing system 100 that is consistent with the invention. The data processing system 100 comprises a processor 110 which sends and receives data for manipulation. The processor 110 requests or sends data using logical addresses for memory locations in a memory 140. A system bus 120 transfers the data and the logical addresses to the translator or directly to the memory 140. A translator 130 is a memory device which can translate logical addresses from the processor 110 via the system bus 120 into physical addresses of the memory 140. For the purposes of this invention the translator 130 will be referred to as a TAG RAM. The translator 130 contains data which can be referred to as a look-up table. The translator 130 can be any type of memory storage device including SRAM, PROM, DRAM etc. Finally there is the memory device 140 which is a DRAM although a person skilled in the art could apply this method to a wide variety of memory devices. The memory 140 is composed of a plurality of memory cells that are arranged in a logical order as so an external device can address a particular area of the memory 140. The number of addresses in a memory 140 depends on the number of memory cells. The memory 140 is shown having high order addresses (H.A.) 142, and having low order addresses (L.A.) 144. However there are many different terms which can be used to describe different memory areas.

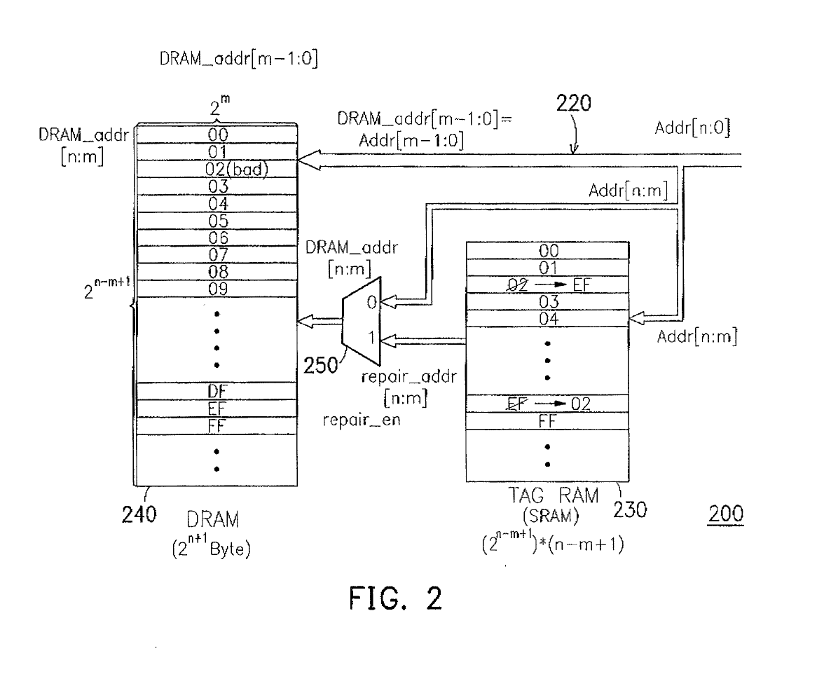

Referring to FIG. 2, a remapping apparatus 200 of a preferred embodiment of the invention is shown where a processor 110 will read or write data. The processor 110 will send signals over a system bus 220 to access a TAG RAM 230, and determine a physical address to correspond to a logical address. The processor 110 will then access a memory area in the DRAM 240 using the physical address that is defined by the TAG RAM 230. The processor also has the ability the bypass the TAG RAM 230 by utilizing a multiplexer 250. The multiplexer 250 is controlled by an enable signal(repair_en) which in effect can serve to route memory access signals around the TAG RAM 230.

The present invention provides a method of remapping DRAM memory as to maximize memory use, and contains two algorithms to that effect. The general repair methodology is as follows. In order to efficiently use a DRAM memory device the processor will activate a routine to map the DRAM. This process serves to identify non-defective memory areas, and defective memory areas. The TAG RAM initially contains a set of logical address that corresponds to physical addresses in the DRAM. When a defective memory area has been identified the repair methodology allows for the swapping of a physical addresses corresponding to a logical address in the TAG RAM look-up table to that of a non-defective physical address. If a request is then made for data at that logical address the look-up table identifies the physical address to be the new non-defective memory area instead of the original defective memory area.

Referring to FIG. 2 a DRAM has a total size of 2ⁿ⁺¹ bytes, and the size of the TAG RAM is 2^{m} bytes. If any defective memory area is discovered, for example block #02, then the look-up table in the TAG RAM is modified with a value of a non-defective block, for example block #EF. This means that the value of physical address #02 in the TAG RAM is replaced by #EF, and the value of physical address #EF is replaced by #02. As shown in FIG. 2 the repaired address (repair_addr[n:m]) will replace the original address (Addr[n:m]), and become the DRAM high bit address (DRAM_addr[n:m]). Therefore after the repair whenever accessing logic space of 02X..Xh, because the high bit address #02 has been replaced with #EF, it will physically access to the space of EFX..Xh.

The methods described herein allow for the number of blocks in the translator to be larger, smaller or equal in size to the number of blocks in the DRAM. This can allow two possible scenarios to occur.

When the number of TAG RAM blocks is larger than or equal to the DRAM block number, all the blocks of DRAM can be accessed. Typically in this situation the defective blocks are swapped with non-defective blocks in the most bottom block. After repair, all the blocks which contain defective blocks are in the bottom of the DRAM, so we can get an unbroken good space at the upper block to store important data. Data that is not so critical can be placed in the bottom block.

When the TAG RAM blocks are smaller than the DRAM blocks, there will be some blocks in the DRAM that cannot be accessed by the TAG RAM. This area can however be mapped and addressed so it will become spare memory. We can swap defective blocks with this spare memory, so after the repair is completed the defective blocks will not be accessed.

In both situations once DRAM repairs have been completed the repaired address (repair_addr[a:m]) in the translator will always replace the original high memory location address. In addition typically the TAG RAM will always be filled with linear data so if no matter if the DRAM repair is enabled or disabled, the logic address should always attempt to equal the physical address.

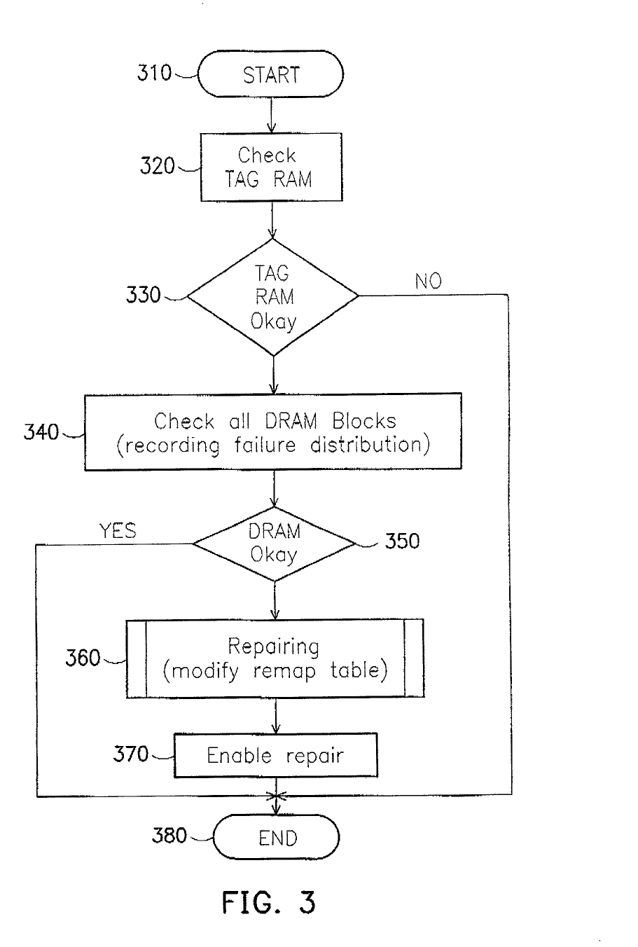

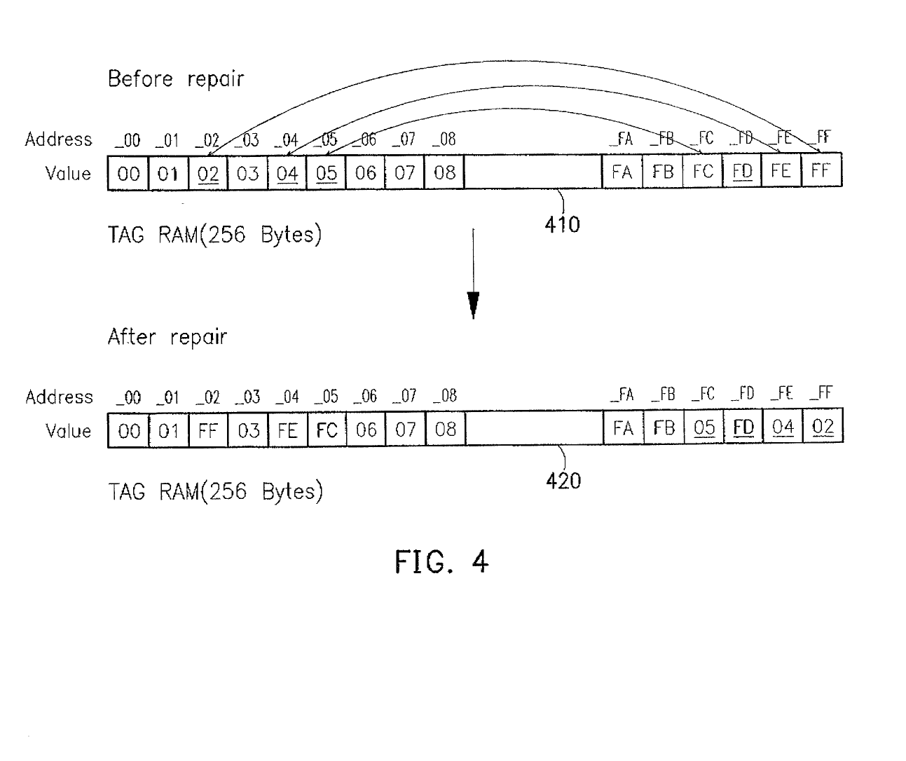

The invention provides two repairing algorithms for swapping defective memory locations with non-defective memory locations. FIG. 3 shows one embodiment with a flowchart of the first algorithm entitled a Rainbow Swapping Algorithm. In step 320 the TAG RAM is tested to ensure it is operating correctly. In step 340 the system maps all blocks in the DRAM to determine which blocks are defective. If the DRAM is okay the programs ends 350 however if defective blocks are found the look-up table is modified 360, and repairs are enabled 370. The Rainbow Swapping algorithm modifies the look-up table by swapping defective blocks in higher address spaces with the next available non-defective block in the lower address space. FIG. 4 shows an example of the Rainbow Swapping method in which the look-up table is modified. In FIG. 4 the width of the TAG RAM is 8 bits and there are 256 slots, i.e. the TAG RAM is 256 bytes. Blocks #02, #04, #05, and #FD are all defective blocks in the DRAM. As shown in diagram 420, block #02 is swapped with #FF, #04 with #FE, and #05 with #FC.

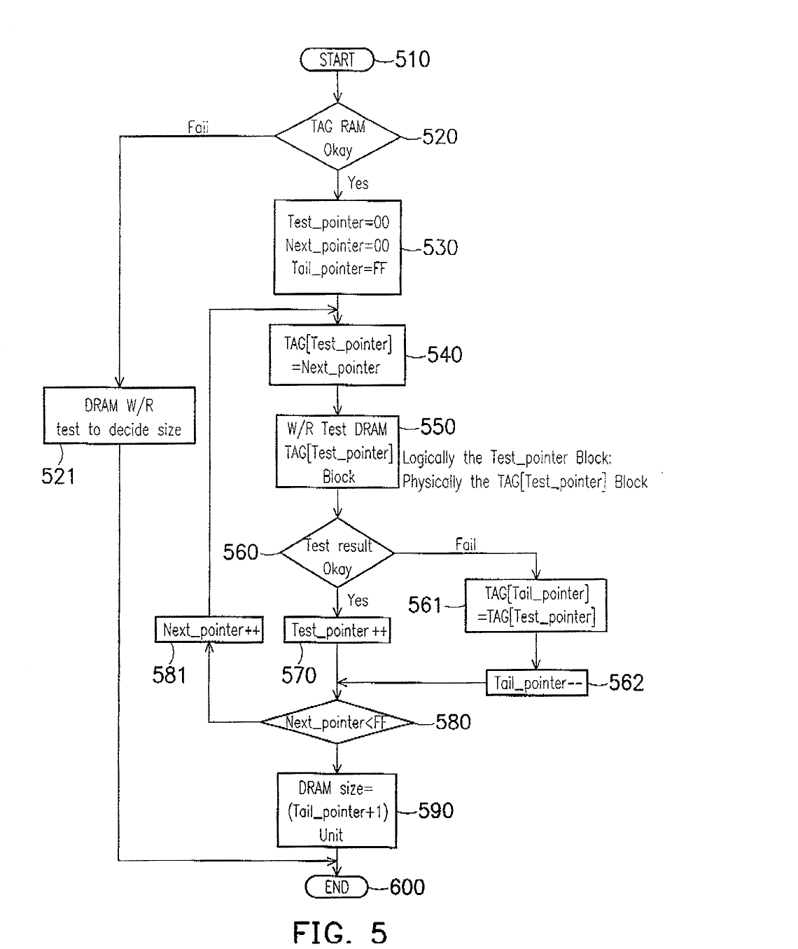

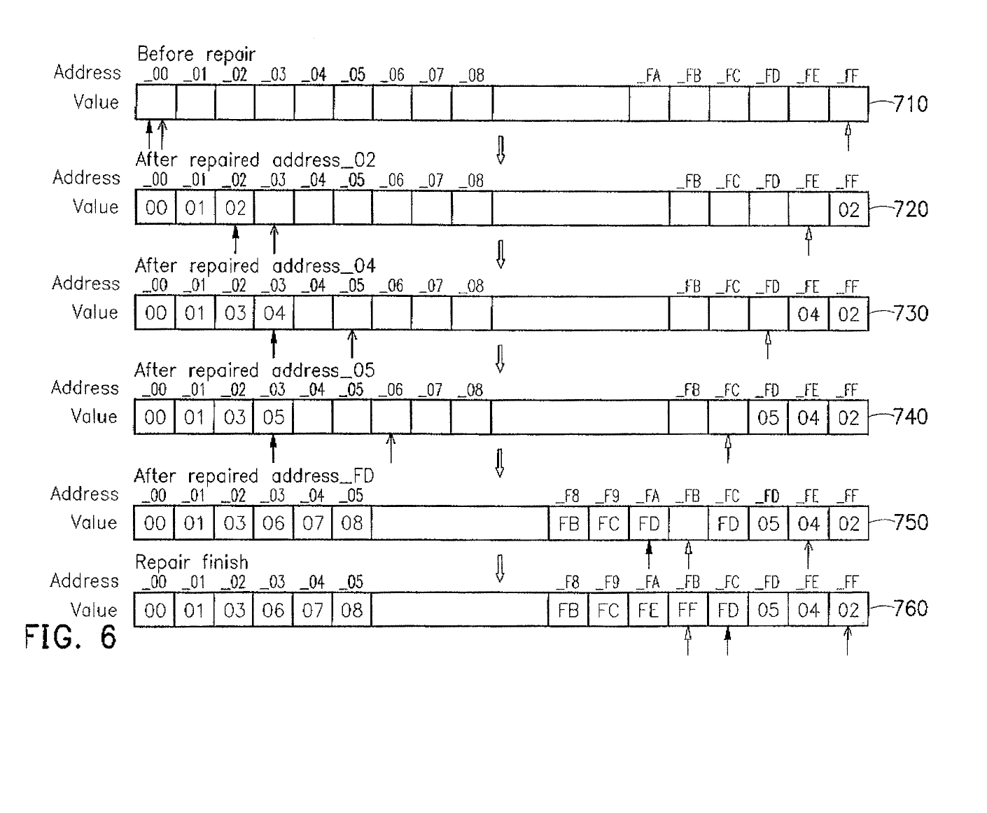

FIG. 5 shows a flowchart exemplifying the Stack Swapping algorithm. The Stack Swapping algorithm provides a method for placing all the defective blocks into one end of the address structure. In step 520 the TAG RAM is tested to ensure it is operating correctly. Next in Step 530 the pointers are all set to their starting positions. The logical address in the TAG RAM that is equal to the test_pointer is then set to be equal to the value of the physical address of the next_pointer 540. The device maps the DRAM block and determines if it is defective or not 550. If a block is non-defective the test_pointer is forwarded in step 570. If the block is found to be defective the value of the tail_pointer, and the test_pointer are made equal in the TAG RAM 561. The tail_pointer is then moved backwards 562. Going to step 580 if the next_pointer is found to equal the last memory address (#FF), then the DRAM size is calculated 590, and the program ends. If the next_pointer does not equal the last memory address (#FF) then the next_pointer is forwarded 581, and the program returns to step 540, and maps the next memory block. The diagram in FIG. 6 shows an example of the Stack Swapping algorithm. In the example the width of the TAG RAM is 8 bits and there are 256 slots, i.e. the TAG RAM is 256 bytes. Blocks #02, #04, #05 and #FD are defective blocks in the DRAM. In section 760 it can be seen that the high addresses all contain non-defective memory blocks while the lower addresses contain the defective memory blocks sequentially.

Various additional modifications may be made to the illustrated embodiments without departing from the spirit and scope of the invention. Therefore, the invention lies in the claims hereinafter appended.

What is claimed is:

1. A method of utilizing a DRAM memory, wherein the DRAM memory may include defective memory locations,
the method comprising:
assigning logical addresses which correspond to physical addresses;
mapping physical addresses wherein defective physical addresses are identified;
swapping a defective physical address of a logical address, with a non-defective physical address.

2. The method of claim 1, further wherein the logical addresses are assigned linearly.

3. The method of claim 1 where the logical addresses are assigned equaling the physical addresses.

4. The method of claim 1, further comprising:
a redundant memory; and
swapping a defective physical addresses of a logical address, with a physical address in the redundant memory.

5. The method of claim 1, wherein the mapping method consists of a read and write testing process.

6. A method of utilizing a DRAM memory, wherein the DRAM memory may include defective memory locations,
the method comprising:
assigning logical addresses which correspond to physical addresses;
mapping physical addresses, wherein defective physical addresses are identified;
sequentially swapping a defective physical address of a logical address at one end of the logical address section, to the first non-defective physical address at the other end of the logical address section that has not already been swapped.

7. The method of claim 6, further wherein the logical addresses are assigned linearly.

8. The method of claim 6, where the logical addresses are assigned equaling the physical addresses.

9. The method of claim 6, further comprising:
a redundant memory; and
swapping a defective physical addresses of a logical address, with a physical address in the redundant memory.

10. The method of claim 6, wherein the mapping method consists of a read and write testing process.

11. A method of utilizing a DRAM memory, wherein the DRAM memory may include defective memory locations,
the method comprising:
assigning logical addresses which correspond to physical addresses;
mapping physical addresses, wherein defective physical addresses are identified;
sequentially moving a defective physical address of a logical address at one end of a logical address section, with the first physical address that has not previously been assigned a defective physical address at the other end of the logical address section; and
sequentially moving a physical address into a logical address where a previous physical address has been moved.

12. The method of claim 11, further wherein the logical addresses are assigned linearly.

13. The method of claim 11, where the logical addresses are assigned equaling the physical addresses.

14. The method of claim 11, wherein the mapping method consists of a read and write testing process.
